(19) United States
(12) Patent Application Publication
(10) Pub. No.: US 2025/0219398 A1
(43) Pub. Date: Jul. 3, 2025

(54) AUTOMOTIVE-GRADE CHIP, PROTECTION CIRCUIT, AND VEHICLE-MOUNTED CIRCUIT

(71) Applicant: Zhuhai Nanxin Semiconductor Technology Co., Ltd, Zhuhai City (CN)

(72) Inventors: Chao Chen, Zhuhai City (CN); Jun Ma, Zhuhai City (CN)

(21) Appl. No.: 19/004,167

(22) Filed: Dec. 27, 2024

(30) Foreign Application Priority Data
Dec. 29, 2023 (CN) 202311862968.0

(51) Int. Cl. H02H 11/00; B60R 16/023

(52) U.S. Cl. CPC H02H 11/003; B60R 16/0232; H02H 11/007

(57) ABSTRACT

The present disclosure provides an automotive-grade chip, and a vehicle-mounted circuit. The automotive-grade chip includes: a plurality of reverse connection protection circuits, a plurality of ports, and an internal circuit assembly. The reverse connection protection circuit is electrically connected between the port and the internal circuit assembly, and the port is further electrically connected to a controller or electrically connected between the controller and a low dropout linear regulator. The reverse connection protection circuit is configured to, in the case that a voltage at a corresponding port is equal to a reverse connection voltage of the controller, cut off a pathway between the port and the internal circuit assembly and/or control the internal circuit assembly to stop functioning. In this way, the internal circuit assembly of the automotive-grade chip is prevented from damages, and reliability of the automotive-grade chip is improved.

### CROSS-REFERENCE TO RELATED APPLICATION

This application is based upon and claims the priority of Chinese Patent Application No. 202311862968.0, filed on Dec. 29, 2023, the entire content of which is hereby incorporated by reference herein and made a part of this specification.

### TECHNICAL FIELD

The present disclosure relates to the technical field of electronics, and in particular, relates to an automotive-grade chip, a protection circuit, and a vehicle-mounted circuit.

### BACKGROUND

Automotive-grade chips (also referred to as core chips) are chips for vehicle control. A ground port of the automotive-grade chip is electrically connected to a ground port of the printed circuit board (PCB), and some ports of the automotive-grade chip are electrically connected to a microcontroller unit (MCU). The automotive-grade chip is configured to control whether a voltage at a power port BAT2 of the PCB supplies power a load (LOAD) during signal transmission with the MCU. Both the automotive-grade chip and the MCU are configured on the PCB.

In related arts, a diode is typically added between a ground port GND1 of the automotive-grade chip and a ground port GND2 of the PCB in a low-side reverse connection protection configuration. This protects the automotive-grade chip in the case that the power supply is reversely connected (i.e., in the case that the ground port GND2 of the PCB is electrically connected to a positive terminal of the power supply).

In the low-side reverse connection protection configuration, voltages on certain ports of the automotive-grade chip are equal to a high voltage (i.e., a power supply voltage), which leads to damages to an internal circuit assembly of the automotive-grade chip. Accordingly, it is urgent to design a circuit to prevent the internal circuit assembly of the automotive-grade chip from damages in the case that the power supply is reversely connected, and improve the reliability of the automotive-grade chip.

### SUMMARY

The present disclosure provides an automotive-grade chip, a circuit, and a device to prevent damages to the internal circuit assembly in the automotive-grade chip in the case that the power supply is reversely connected. This prevents the internal circuit assembly of the automotive-grade chip from damages and improves the reliability of the automotive-grade chip.

According to a first aspect, the present disclosure provides an automotive-grade chip. The automotive-grade chip includes: a plurality of reverse connection protection circuits, a plurality of ports, and an internal circuit assembly. The reverse connection protection circuit is electrically connected between the port and the internal circuit assembly. The port is further electrically connected to a controller or electrically connected between the controller and a low dropout linear regulator.

The reverse connection protection circuit is configured to, in a case that a voltage at a corresponding port is equal to a reverse connection voltage of the controller, cut off a pathway between the port and the internal circuit assembly and/or control the internal circuit assembly to stop functioning.

In the automotive-grade chip according to the first aspect, a reverse connection protection circuit corresponding to a port is arranged. In the case that the voltage at the corresponding port is equal to the reverse connection voltage of the controller (i.e., in the case that the voltage at the corresponding port is equal to a high voltage), the pathway between the corresponding port and the internal circuit assembly is cut off and/or the internal circuit assembly is controlled to stop functioning. This prevents the internal circuit assembly from operating under the high voltage, thereby preventing the internal circuit assembly from damages and improving the reliability of the automotive-grade chip.

In a possible design, the plurality of reverse connection protection circuits include: a first reverse connection protection circuit, a second reverse connection protection circuit, and a third reverse connection protection circuit. A port corresponding to the first reverse connection protection circuit is a serial peripheral interface. A port corresponding to the second reverse connection protection circuit is a first port. A port corresponding to the third reverse connection protection circuit is a serial data output port. The internal circuit assembly includes a first internal circuit and a second internal circuit. The first reverse connection protection circuit is electrically connected to the first internal circuit, the second internal circuit, and the third reverse connection protection circuit, the second reverse connection protection circuit is electrically connected between the first port and the first internal circuit, the third reverse connection protection circuit is electrically connected between the serial data output port and the second internal circuit, and the third reverse connection protection circuit is further electrically connected to the serial peripheral interface.

The first reverse connection protection circuit is configured to, in a case that a voltage at the serial peripheral interface is equal to the reverse connection voltage, cut off a pathway between the serial peripheral interface and the first internal circuit, cut off a pathway between the serial peripheral interface and the second internal circuit, and cut off a pathway between the serial peripheral interface and the third reverse connection protection circuit.

The second reverse connection protection circuit is configured to, in response to a voltage at the first port being equal to the reverse connection voltage, cut off a pathway between the first port and the first internal circuit.

The third reverse connection protection circuit is configured to, in response to a voltage at the serial data output port being equal to the reverse connection voltage, control the second internal circuit to stop functioning.

In a possible design, the first reverse connection protection circuit comprises: a first high-voltage transistor, a first low-voltage transistor, a second low-voltage transistor, and a first clamp diode, and a first current source.

A first terminal of the first high-voltage transistor is electrically connected to the serial peripheral interface, a second terminal of the first high-voltage transistor is electrically connected to the first internal circuit, the second internal circuit, and the third reverse connection protection circuit, a first terminal of the first current source is connected to a charge pump output voltage of the automotive-grade chip, a second terminal of the first current source is electrically connected to a cathode of the first clamp diode, an anode of the first clamp diode is electrically connected to a second terminal of the second low-voltage transistor, a first terminal of the second low-voltage transistor is electrically connected to a second terminal of the first low-voltage transistor, a first terminal of the first low-voltage transistor is electrically connected to a ground port of the automotive-grade chip, a control terminal of the first high-voltage transistor is electrically connected between the second terminal of the first current source and the cathode of the first clamp diode, a control terminal of the second low-voltage transistor is electrically connected between the first terminal of the second low-voltage transistor and the second terminal of the first low-voltage transistor, and a control terminal of the first low-voltage transistor is electrically connected between the first terminal of the first low-voltage transistor and the ground port of the automotive-grade chip.

In a possible design, the second reverse connection protection circuit includes: a first resistor and a second high-voltage transistor.

A first terminal of the first resistor is electrically connected to the first port, a second terminal of the first resistor is electrically connected to a first terminal of the second high-voltage transistor, a second terminal of the second high-voltage transistor is electrically connected to a second input terminal of the first internal circuit, and a control terminal of the second high-voltage transistor is connected to a reference voltage.

In a possible design, the first port includes a serial clock port and/or a serial data input port.

In a possible design, the third reverse connection protection circuit includes: a second clamp diode, a third clamp diode, a fourth clamp diode, a second resistor, a third resistor, a fourth resistor, a fifth resistor, a third high-voltage transistor, a third low-voltage transistor, a fourth low-voltage transistor, and a fifth low-voltage transistor.

The serial peripheral interface is electrically connected to the second internal circuit, a cathode of the third clamp diode is electrically connected between the serial peripheral interface and the second internal circuit, an anode of the third clamp diode is electrically connected to a first terminal of the second resistor, a second terminal of the second resistor is electrically connected to a first terminal of the third resistor, and a second terminal of the third resistor is electrically connected to a ground port of the automotive-grade chip.

A cathode of the second clamp diode is electrically connected between the serial peripheral interface and the second internal circuit, an anode of the second clamp diode is electrically connected to a second terminal of the third high-voltage transistor, a first terminal of the third high-voltage transistor is electrically connected to the ground port of the automotive-grade chip, a control terminal of the third high-voltage transistor is electrically connected between the anode of the third clamp diode and the first terminal of the second resistor, and the second internal circuit is further electrically connected between the anode of the second clamp diode and the second terminal of the third high-voltage transistor.

A cathode of the fourth clamp diode, a control terminal of the third low-voltage transistor, and a control terminal of the fourth low-voltage transistor are all electrically connected between the second terminal of the second resistor and the first terminal of the third resistor, an anode of the fourth clamp diode, a second terminal of the third low-voltage transistor, a second terminal of the fourth low-voltage transistor, and a second terminal of the fifth low-voltage transistor are all electrically connected between the second terminal of the third resistor and the ground port of the automotive-grade chip, a first terminal of the third low-voltage transistor is electrically connected to the second internal circuit, a first terminal of the fourth low-voltage transistor is electrically connected to the first reverse connection protection circuit via the fourth resistor, a control terminal of the fifth low-voltage transistor is electrically connected between the first terminal of the fourth low-voltage transistor and the fourth resistor, and a first terminal of the fifth low-voltage transistor is electrically connected between the second internal circuit and the second terminal of the third high-voltage transistor via the fifth resistor.

According to a second aspect, the present disclosure provides a protection circuit, applicable to an automotive-grade chip according to the first aspect. The protection circuit includes: a switch and a voltage controller. A first terminal of the switch is electrically connected to a ground port of a printed circuit board, a second terminal of the switch is electrically connected to the ground port of the automotive-grade chip, a control terminal of the switch is electrically connected to a first terminal of the voltage controller, a second terminal of the voltage controller is electrically connected between the second terminal of the switch and the ground port of the automotive-grade chip, and a third terminal of the voltage controller is electrically connected to a power port of the printed circuit board. The automotive-grade chip, the switch, the voltage controller, and the protection circuit are arranged on the printed circuit board.

The voltage controller is configured to, in a case that a voltage at the power port of the printed circuit board is less than the reverse connection voltage, control the switch to turn off to cut off a pathway between the ground port of the printed circuit board and the ground port of the automotive-grade chip; and in a case that the voltage at the power port of the printed circuit board is equal to the reverse connection voltage, control the switch to turn on to conduct the pathway between the ground port of the printed circuit board and the ground port of the automotive-grade chip, wherein a voltage drop is less than a predetermined voltage threshold in a case that the switch is turned on.

In the embodiments of the present disclosure, in the case that the power supply is reversely connected, the voltage controller controls the switch to turn off to cut off the pathway between the ground port of the printed circuit board and the ground port of the automotive-grade chip. This prevents the internal circuit assembly from operating under high voltages, protects the internal circuit assembly from damages, and enhances the reliability of the automotive-grade chip. In the case that the power supply is positively connected, the voltage controller controls the switch to turn on to conduct the pathway between the ground port of the printed circuit board and the ground port of the automotive-grade chip. Since the voltage drop is less than the predetermined voltage threshold in the case that the switch is turned on, the cold-start performance of the automotive-grade chip is improved.

In a possible design, the switch includes: a fourth high-voltage transistor.

A first terminal of the fourth high-voltage transistor is electrically connected to the ground port of the printed circuit board, a second terminal of the fourth high-voltage transistor is electrically connected to the ground port of the automotive-grade chip, and a control terminal of the fourth high-voltage transistor is electrically connected to the first terminal of the voltage controller.

In a possible design, the voltage controller includes: a seventh high-voltage transistor, a fifth resistor, an eighth resistor, an eighth high-voltage transistor, a fifth clamp diode, and a second current source.

A second terminal of the seventh high-voltage transistor, a first terminal of the fifth resistor, and a first terminal of the eighth resistor are all electrically connected to the power port of the printed circuit board, a control terminal of the seventh high-voltage transistor is electrically connected to a control terminal of the eighth high-voltage transistor, a second terminal of the eighth resistor is electrically connected between the control terminal of the seventh high-voltage transistor and the control terminal of the eighth high-voltage transistor, a second terminal of the fifth resistor is electrically connected to a second terminal of the eighth high-voltage transistor, a first terminal of the eighth high-voltage transistor is electrically connected to the control terminal of the fourth high-voltage transistor, the first terminal of the fourth high-voltage transistor is electrically connected to the ground port of the printed circuit board, the second terminal of the fourth high-voltage transistor is electrically connected to the ground port of the automotive-grade chip, a cathode of the fifth clamp diode is electrically connected between the first terminal of the eighth high-voltage transistor and the control terminal of the fourth high-voltage transistor, an anode of the fifth clamp diode is electrically connected between the second terminal of the fourth high-voltage transistor and the ground port of the automotive-grade chip, and a first terminal of the seventh high-voltage transistor is connected between the second terminal of the fourth high-voltage transistor and the ground port of the automotive-grade chip via the second current source.

In a possible design, the voltage controller further includes: a sixth low-voltage transistor and a seventh low-voltage transistor.

A second terminal of the sixth low-voltage transistor is electrically connected to the power port of the printed circuit board, a first terminal of the sixth low-voltage transistor is electrically connected to a second terminal of the seventh low-voltage transistor, a control terminal of the sixth low-voltage transistor is electrically connected between the first terminal of the sixth low-voltage transistor and the second terminal of the seventh low-voltage transistor, and a first terminal of the seventh low-voltage transistor and the a control terminal of the seventh low-voltage transistor are both electrically connected between the control terminal of the seventh high-voltage transistor and the control terminal of the eighth high-voltage transistor.

According to a third aspect, the present disclosure provides a vehicle-mounted circuit. The vehicle-mounted circuit includes: a controller, a low dropout linear regulator, a first reverse connection protection diode, a second reverse connection protection diode, and an automotive-grade chip according to the first aspect.

An anode of the second reverse connection protection diode is electrically connected to the power port of the printed circuit board, a cathode of the second reverse connection protection diode is electrically connected to an input terminal of the low dropout linear regulator, an output terminal of the low dropout linear regulator is electrically connected to an input terminal of the controller, and a ground terminal of the controller is electrically connected to the ground port of the printed circuit board.

A first port and a serial data output port the automotive-grade chip are electrically connected to the controller, a serial peripheral interface of the automotive-grade chip is electrically connected between an output terminal of the low dropout linear regulator and a voltage input terminal of the controller, a power port of the automotive-grade chip is electrically connected to a power port of the printed circuit board, a ground port of the automotive-grade chip is electrically connected to an anode of the first reverse connection protection diode, and a cathode of the first reverse connection protection diode is electrically connected to the ground port of the printed circuit board.

For details about the beneficial effects achieved by the vehicle-mounted circuit according to the third aspect, reference may be made to the beneficial effects achieved by the first aspect or any possible design of the first aspect, which are not described herein any further.

In a fourth aspect, the present disclosure provides a vehicle-mounted circuit. The vehicle-mounted circuit includes: a controller, a low dropout linear regulator, a second reverse connection protection diode, the automotive-grade chip according to any possible design of the first aspect, and the protection circuit according to any possible design of the second aspect.

An anode of the second reverse connection protection diode is electrically connected to the power port of the printed circuit board, a cathode of the second reverse connection protection diode is electrically connected to an input terminal of the low dropout linear regulator, an output terminal of the low dropout linear regulator is electrically connected to a voltage input terminal of the controller, and a ground terminal of the controller is electrically connected to the ground port of the printed circuit board.

A first port and a serial data output port of the automotive-grade chip are electrically connected to the controller, a serial peripheral interface of the automotive-grade chip is electrically connected between an output terminal of the low dropout linear regulator and a voltage input terminal of the controller, a power port of the automotive-grade chip is electrically connected to a power port of the printed circuit board, a ground port of the automotive-grade chip is electrically connected to a first terminal of the protection circuit, a second terminal of the protection circuit is electrically connected to a ground port of the printed circuit board, and a third terminal of the protection circuit is electrically connected to the power port of the printed circuit board.

For details about the beneficial effects achieved by the vehicle-mounted circuit according to the fourth aspect, reference may be made to the beneficial effects achieved by the first aspect or any possible design of the first aspect, or the second aspect or any possible design of the second aspect, which are not described herein any further.

In a fifth aspect, the present disclosure provides a vehicle. The vehicle includes the vehicle-mounted circuit according to the third aspect or the fourth aspect.

For details about the beneficial effects achieved by the vehicle according to the fifth aspect, reference may be made to the beneficial effects achieved by the third aspect or the fourth aspect, which are not described herein any further.

### BRIEF DESCRIPTION OF THE DRAWINGS

FIG. 1 is a schematic structural diagram of a printed circuit board (PCB) in the related art;

FIG. 2 is a schematic structural diagram of a high-side protection scheme in the related art;

FIG. 3 is a schematic structural diagram of a low-side protection scheme in the related art;

FIG. 4 is a schematic structural diagram of a vehicle-mounted circuit according to some embodiments of the present disclosure;

FIG. 5 is a schematic structural diagram of a vehicle-mounted circuit according to some embodiments of the present disclosure;

FIG. 6 is a schematic structural diagram of an automotive-grade chip according to some embodiments of the present disclosure;

FIG. 7 is a schematic structural diagram of an automotive-grade chip according to some embodiments of the present disclosure;

FIG. 8 is a schematic structural diagram of a first reverse connection protection circuit according to some embodiments of the present disclosure;

FIG. 9 is a schematic structural diagram of a second reverse connection protection circuit according to some embodiments of the present disclosure;

FIG. 10 is a schematic structural diagram of a third reverse connection protection circuit according to some embodiments of the present disclosure;

FIG. 11 is a schematic structural diagram of a protection circuit 006 according to some embodiments of the present disclosure;

FIG. 12 is a schematic structural diagram of a switch according to some embodiments of the present disclosure;

FIG. 13 is a schematic structural diagram of a voltage controller according to some embodiments of the present disclosure; and

FIG. 14 is a schematic structural diagram of a voltage controller according to some embodiments of the present disclosure.

### DETAILED DESCRIPTION

In the present disclosure, the term “at least one” refers to one or more than one, and the term “a plurality of” refers to two or more than two. The term “and/or” is merely an association relationship for describing associated objects, which represents that there may exist three types of relationships, for example, A and/or B may represent three situations: only A exists, both A and B exist, and only B exists, wherein A and B may be single or plural. In addition, the symbol “/” generally represents an “or” relationship between associated objects before and after the symbol. The expression “at least one of the following” or the like expression means any combination of the items or options listed, including a single item or option or any combination of plural items or options listed. For example, at least one of a single a, a single b, and a single c may indicate: the single a, the single b, the single c, a combination of a and b, a combination of a and c, a combination of b and c, or a combination of a, b, and c, wherein each of a, b, and c may be single or plural.

In the description of the present disclosure, it should be understood that the terms “central,” “transversal,” “longitudinal,” “upper,” “lower,” “left,” “right,” “front,” “rear,” and the like indicate orientations and position relationships which are based on the illustrations in the accompanying drawings, and these terms are merely for ease and brevity of the description, instead of indicating or implying that the devices or elements shall have a particular orientation and shall be structured and operated based on the particular orientation. Accordingly, these terms shall not be construed as limiting the present disclosure.

In the description of the present disclosure, unless otherwise explicitly specified and defined, the terms “connected,” “coupled,” and derivatives forms thereof shall be understood in a broad sense. For example, the terms “connected,” “coupled,” and derivatives form thereof for depicting the circuit structure, in addition to physical connection, may also be understood as electrical connections or signal connection. The connection, for example, may be direct connection, i.e., the physical connection or, indirect connection via at least one intermediate element as long as the circuit is conducted, or communication between the interiors of two elements. Signal connection refers not only to signal transmission via circuits but also to signal transmission via media, such as radio waves. Persons of ordinary skill in the art may understand specific meanings of the above terms in the present disclosure according to the actual circumstances and contexts.

In the description of the embodiments of the present disclosure, terms such as “exemplary,” “for example,” or “by way of example” are used to indicate instances, illustrations, or explanations. Any embodiment or design described as “exemplary,” “for example,” or “by way of example” in the present disclosure should not be interpreted as being preferred or superior to other embodiments or designs. Rather, the use of terms like “exemplary,” “for example,” or “by way of example” is intended to present the relevant concepts in a specific manner.

In addition, terms of “first,” “second,” and the like are only used for description, but shall not be understood as indication or implication of relative importance or implicit indication of the specific technical features. Therefore, the features defined by the terms “first” and “second” may explicitly or implicitly include one or more of these features. The terms “include,” “comprise,” “contain,” “have,” and their variations all imply “including but not limited to,” unless otherwise specified.

Hereinafter, the terms involved in embodiments of the present disclosure are described first.

Positive power connection means that a power port BAT2 of a printed circuit board (PCB) is electrically connected to a positive terminal of a power supply, and a ground port GND2 of the PCB is electrically connected to a negative terminal of the power supply. In the case that the power supply is positively connected, the power port BAT2 of the PCB has a high voltage (that is, voltage of the power supply), and a voltage at the ground port GND2 of the PCB is 0 V. In some possible designs, the high voltage may be equal to 14 V or 24 V.

Reverse power connection means that the power port BAT2 of the PCB is electrically connected to a negative terminal of the power supply, and the ground port GND2 of the PCB is electrically connected to the positive terminal of the power supply. In the case that the power supply is reversely connected, the voltage at the power port BAT2 of the PCB is 0 V (that is, the power port BAT2 is considered to have a zero potential), and a high voltage is present at the ground port GND2 of the PCB.

A reverse connection voltage of a controller refers to a voltage of the controller in the case that the power supply is reversely connected, and the reverse connection voltage is equal to the voltage at the ground port GND2 of the PCB. That is, in the case that the power supply is reversely connected, and the reverse connection voltage of the controller is high.

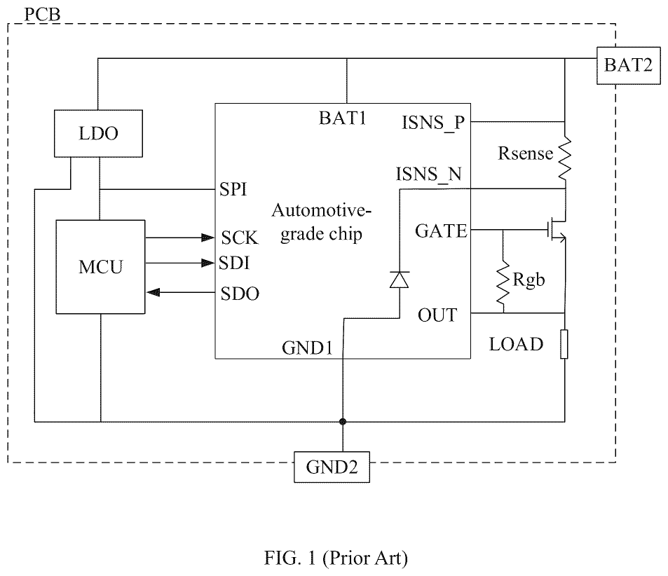

FIG. 1 is a schematic structural diagram of a PCB in the related art. As illustrated in FIG. 1, the PCB includes an automotive-grade chip, a low dropout linear regulator (LDO), a microcontroller unit (MCU), a sense resistor Rsense, a resistor Rgb, and a transistor M1.

The PCB has a ground port GND2 and a power port BAT2. The automotive-grade chip has a serial peripheral interface (SPI), a serial clock (SCK) port, a serial data input (SDI) port, a serial data output (SDO) port, a power port BAT1, a ground port GND1, a current sense amplifier positive input (ISNS_P), a current sense amplifier negative input (ISNS_N), a control port GATE, and an output port OUT. The SPI is configured to receive a low voltage provided by the low dropout linear regulator. The SCK port, the SDI port, the SDO port are configured to perform information transmission with the MCU. The power port BAT1 is configured to receive a high voltage provided by the power port BAT2 of the PCB in the case that the power port BAT2 of the PCB is electrically connected to the positive terminal of the power supply.

Electrical connections of the automotive-grade chip, the LDO, the MCU, the sense resistor Rsense, the resistor Rgb and the transistor M1 are illustrated in FIG. 1, which are not described in detail herein.

During the normal functioning of the automotive-grade chip, based on the high voltage at the power port BAT2 of the PCB and the low voltage of the LDO, the transistor M1 is controlled to be turned on or turned off in information transmission with the MCU. The transistor M1 is turned on, and the voltage at the power port BAT2 of the PCB powers a load. The transistor M1 is turned off, and the voltage at the power port BAT2 of the PCB stops powering a load.

In the case that the power supply is positively connected, the MCU has a low voltage, the SPI, the SCK port, the SDI port, the SDO port each have a low voltage, and the automotive-grade chip functions properly. In the case that the power supply is reversely connected, the MCU has a high voltage, the SPI, the SCK port, the SDI port, the SDO port each have a high voltage, and an internal circuit of the automotive-grade chip may be damaged.

In the related arts, in the case that the power supply is reversely connected, to prevent the internal circuit assembly of the automotive-grade chip from damages and improve the reliability of the automotive-grade chip, the automotive-grade chip is generally protected using a high-side protection scheme or a low-side protection scheme.

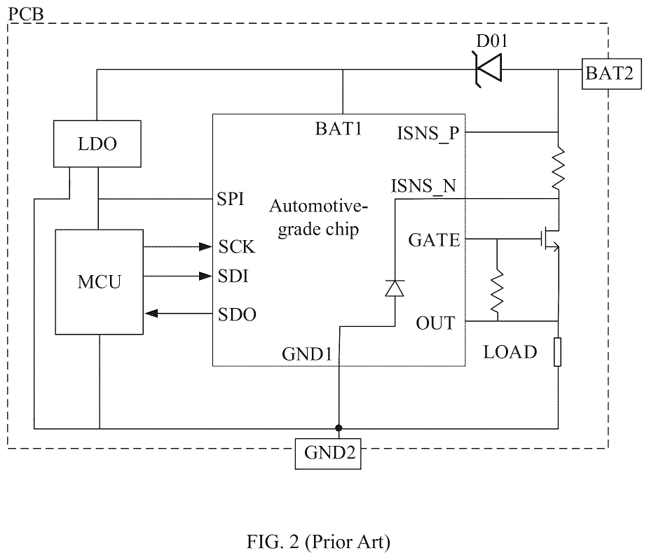

FIG. 2 is a schematic structural diagram of a high-side protection scheme in the related art. Based on FIG. 1, as illustrated in FIG. 2, a reverse connection protection diode D01 is added at the power port BAT2 of the PCB.

In practice, the lower the current-carrying capacity, the lower the cost of the diode; and the higher the current-carrying capacity, the higher the cost of the diode. In the high-side protection scheme, since the reverse connection protection diode D01 requires stronger current-carrying capacity, the cost of the high-side protection scheme is high.

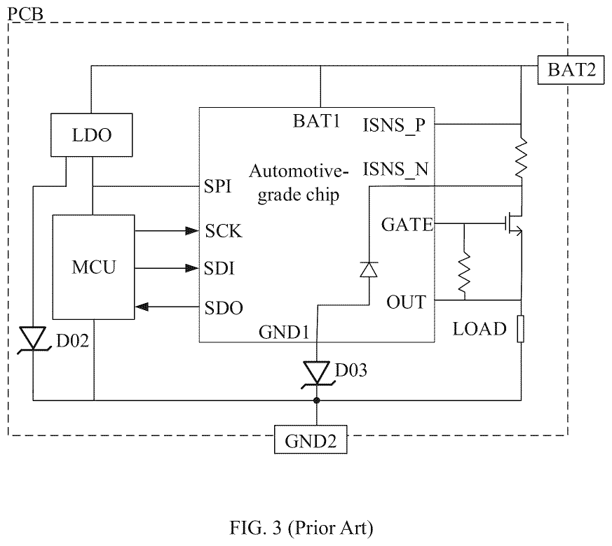

FIG. 3 is a schematic structural diagram of a low-side protection scheme in the related art. Based on FIG. 1, as illustrated in FIG. 3, a reverse connection protection diode D02 is added between the ground port GND2 of the PCB and the LDO, and a reverse connection protection diode D03 is added between the ground port GND2 of the PCB and the ground port GND1 of the automotive-grade chip.

In the low-side protection scheme, in the case that the power supply is reversely connected, a high voltage is present at the ground port GND2 of the PCB, and the voltage of the MCU is equal to the voltage at the ground port GND2 of the PCB, such that the SPI, the SCK port, the SDI port, and the SDO port of the automotive-grade chip all have a high voltage. Consequently, damages are caused to the internal circuit assembly of the automotive-grade chip.

In the case that the power supply is reversely connected, to prevent the internal circuit assembly of the automotive-grade chip from damages, some embodiments of the present disclosure provide an automotive-grade chip. A plurality of reverse connection protection circuits are arranged between a plurality of ports and an internal circuit assembly of the automotive-grade chip. The plurality of reverse connection protection circuits are configured to protect the internal circuit assembly of the automotive-grade chip from damages in the case that voltages at corresponding ports are equal to a reverse connection voltage of a controller (for simplicity, description is given using an example where the controller is an MCU).

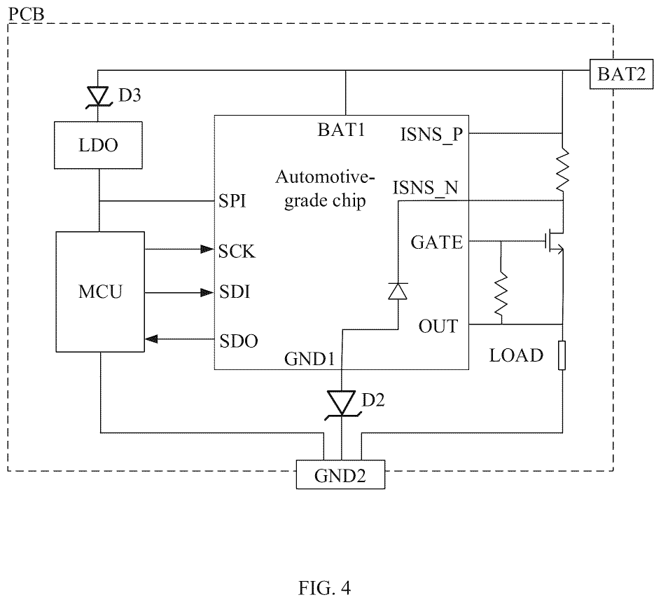

FIG. 4 is a schematic structural diagram of a vehicle-mounted circuit according to some embodiments of the present disclosure. As illustrated in FIG. 4, the vehicle-mounted circuit includes a controller (an MCU), an LDO, a first reverse connection protection diode D2, a second reverse connection protection diode D3, and the automotive-grade chip according to the embodiments of the present disclosure.

An anode of the second reverse connection protection diode D3 is electrically connected to the power port BAT2 of the PCB, and a cathode of the second reverse connection protection diode D3 is electrically connected to an input terminal of the LDO. An output terminal of the LDO is electrically connected to an input terminal of a controller.

A ground terminal of the controller is electrically connected to the ground port GND2 of the PCB.

A first port of the automotive-grade chip and an SDO port are electrically connected to the controller, an SPI of the automotive-grade chip is electrically connected between an output terminal of the LDO and a voltage input terminal of the controller, a power port BAT1 of the automotive-grade chip is electrically connected to a power port BAT2 of the PCB, a ground port GND1 of the automotive-grade chip is electrically connected to an anode of the first reverse connection protection diode D2, and a cathode of the first reverse connection protection diode D2 is electrically connected to the ground port GND2 of the PCB.

The vehicle-mounted circuit according to the embodiment illustrated in FIG. 4 is capable of preventing the internal circuit assembly of the automotive-grade chip from damages, and improving the reliability of the automotive-grade chip.

In the embodiments of the present disclosure, the first port includes, for example, an SCK port and/or an SDI port.

Some embodiments of the present disclosure further provide a vehicle. The vehicle includes, for example, the vehicle-mounted circuit as illustrated in FIG. 4, and is capable of preventing the internal circuit assembly of the automotive-grade chip from damages, and improving the reliability of the automotive-grade chip.

In practice, the automotive-grade chip also needs to support cold-start. That is, in a low-temperature environment, in the case that the voltage of the power supply is less than 3 V, the automotive-grade chip still needs to function properly.

In the low-side protection scheme illustrated in FIG. 3, a reverse connection protection diode D03 is added between the ground port GND2 of the PCB and the ground port GND1 of the automotive-grade chip. In the vehicle-mounted circuit illustrated in FIG. 4, the first reverse connection protection diode D2 is arranged between the automotive-grade chip and the ground port GND2 of the PCB.

In the case that the power supply is positively connected, since a voltage drop (for example, 0.7 V or 0.5 V) of the reverse connection protection diode is large, a voltage drop of the internal power supply of the automotive-grade chip is great, which causes poor cold-start performance of the automotive-grade chip.

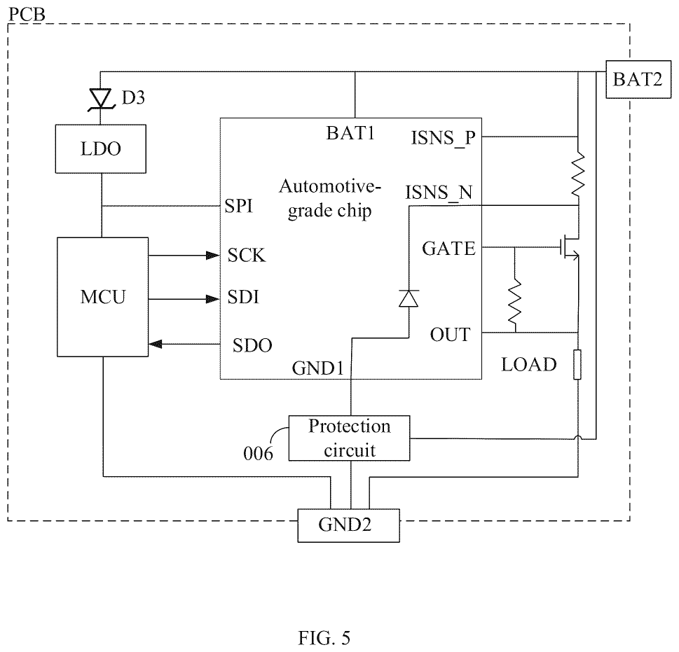

In the case that the power supply is positively connected, to improve the cold-start performance of the automotive-grade chip, some embodiments of the present disclosure provide a protection circuit 006. The vehicle-mounted circuit where the protection circuit 006 is arranged is described with the reference to FIG. 5.

FIG. 5 is a schematic structural diagram of a vehicle-mounted circuit according to some embodiments of the present disclosure. As illustrated in FIG. 5, the vehicle-mounted circuit includes an MCU, an LDO, a second reverse connection protection diode D3, an automotive-grade chip, and the protection circuit 006 according to the embodiments of the present disclosure. The automotive-grade chip is any one of the automotive-grade chips as described in FIG. 5 to FIG. 10.

An anode of the second reverse connection protection diode D3 is electrically connected to the power port BAT2 of the PCB, a cathode of the second reverse connection protection diode D3 is electrically connected to an input terminal of the LDO, an output terminal of the LDO is electrically connected to a voltage input terminal of the controller, and a ground terminal of the controller is electrically connected to the ground port GND2 of the PCB. A first port of the automotive-grade chip and an SDO port are electrically connected to the controller, an SPI of the automotive-grade chip is electrically connected between an output terminal of the LDO and a voltage input terminal of the controller, the power port BAT1 of the automotive-grade chip is electrically connected to the power port BAT2 of the PCB, a ground port GND1 of the automotive-grade chip is electrically connected to a first terminal of the protection circuit 006, a second terminal of the protection circuit 006 is electrically connected to the ground port GND2 of the PCB, and a third terminal of the protection circuit 006 is electrically connected to the power port BAT2 of the PCB.

The vehicle-mounted circuit according to the embodiment illustrated in FIG. 5 is capable of preventing the internal circuit assembly of the automotive-grade chip from damages, improving the reliability of the automotive-grade chip, and enhancing cold-start performance of the automotive-grade chip.

Some embodiments of the present disclosure further provide a vehicle. The vehicle includes, for example, the vehicle-mounted circuit as illustrated in FIG. 5, and is capable of preventing the internal circuit assembly of the automotive-grade chip from damages, and improving the reliability and cold-start performance of the automotive-grade chip.

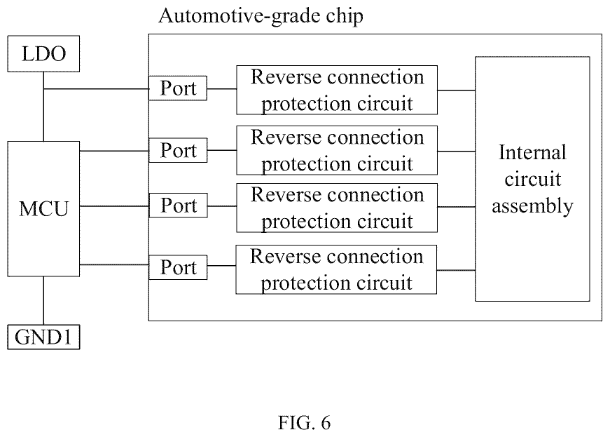

FIG. 6 is a schematic structural diagram of an automotive-grade chip according to some embodiments of the present disclosure. As illustrated in FIG. 6, the automotive-grade chip includes: a plurality of reverse connection protection circuits, a plurality of ports, and an internal circuit assembly. The plurality of reverse connection protection circuits are in one-to-one correspondence with the plurality of ports. For simplification of description, FIG. 6 uses four ports as an example for illustration.

Each of the reverse connection protection circuits is electrically connected between the corresponding port and the internal circuit assembly.

The plurality of ports, for example, include: an SPI, an SDO port, and a first port.

Each of the ports is further electrically connected to a controller or electrically connected between the controller and an LDO.

For example, in the case that one of the ports is an SPI, the port is further electrically connected to the controller or electrically connected between the controller and the LDO.

For example, in the case that one of the ports is an SDO port or a first port, the port is electrically connected to the controller.

Based on the electrical connection as illustrated in FIG. 6, in the case that a voltage at a corresponding port is equal to a reverse connection voltage of the controller, the reverse connection protection circuit cuts off a pathway between the corresponding port and the internal circuit assembly and/or control the internal circuit assembly to stop functioning.

In the case that the power supply is reversely connected, the reverse connection voltage of the controller is equal to the voltage at the ground port GND2 of the PCB. That is, the reverse connection voltage of the controller is equal to a high voltage.

In the embodiments of the present disclosure, a reverse connection protection circuit corresponding to a port is arranged in the automotive-grade chip. In the case that the voltage at the corresponding port is equal to the reverse connection voltage of the controller (i.e., in the case that the voltage at the corresponding port is equal to a high voltage), the pathway between the corresponding port and the internal circuit assembly is cut off and/or the internal circuit assembly is controlled to stop functioning. This prevents the internal circuit assembly from operating under the high voltage, thereby preventing the internal circuit assembly from damages and improving the reliability of the automotive-grade chip.

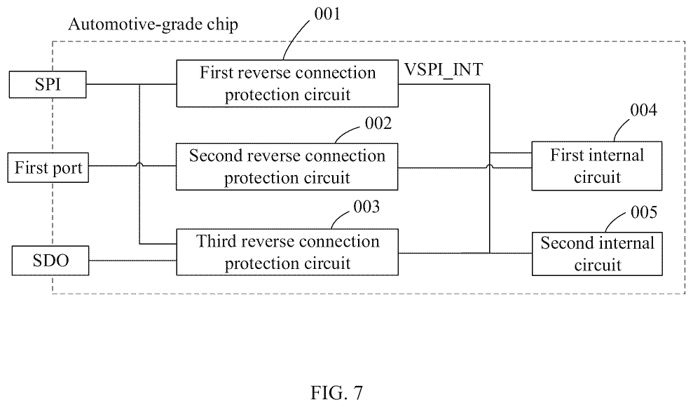

FIG. 7 is a schematic structural diagram of an automotive-grade chip according to some embodiments of the present disclosure. Based on FIG. 6, as illustrated in FIG. 7, the plurality of reverse connection protection circuits include: a first reverse connection protection circuit 001, a second reverse connection protection circuit 002, and a third reverse connection protection circuit 003.

A port corresponding to the first reverse connection protection circuit 001 is an SPI.

A port corresponding to the second reverse connection protection circuit 002 is a first port.

A port corresponding to the third reverse connection protection circuit 003 is an SDO port.

The internal circuit assembly includes a first internal circuit 004 and a second internal circuit 005.

The first reverse connection protection circuit 001 is electrically connected to the first internal circuit 004, the second internal circuit 005, and the third reverse connection protection circuit 003, the second reverse connection protection circuit 002 is electrically connected between the first port and the first internal circuit 004, the third reverse connection protection circuit 003 is electrically connected between the SDO port and the second internal circuit 005, and the third reverse connection protection circuit 003 is further electrically connected to the SPI.

It should be noted that in the case that the first port includes an SCK port and an SDI port, the automotive-grade chip includes the first internal circuit 004 corresponding to the SCK port, the first internal circuit 004 corresponding to the SDI port, and the second reverse connection protection circuit 002 corresponding to two first internal circuits 004.

The first internal circuit 004 corresponding to the SCK port may be, for example, a first digital circuit, and the first internal circuit 004 corresponding to the SDI port may be, for example, a second digital circuit. The first digital circuit and the second digital circuit have the same structure.

The first reverse connection protection circuit 001 is configured to provide a voltage VSPI_INT to the first internal circuit 004 and the second internal circuit 005, or to cut off a pathway between the serial peripheral interface and the internal circuit assembly.

The second reverse connection protection circuit 002 is configured to cut off a pathway between the first port and the first internal circuit 004.

The third reverse connection protection circuit 003 is configured to control the second internal circuit 005 to stop functioning.

Based on the electrical connection as illustrated in FIG. 7, in the case that a voltage at the SPI is equal to the reverse connection voltage, the first reverse connection protection circuit 001 cuts off a pathway between the SPI and the first internal circuit 004, cuts off a pathway between the SPI and the second internal circuit 005, and cuts off a pathway between the SPI and the third reverse connection protection circuit 003. In the case that a voltage at the first port is equal to the reverse connection voltage, the second reverse connection protection circuit 002 cuts off a pathway between the first port and the first internal circuit 004. In the case that a voltage at the SDO port is equal to the reverse connection voltage, the third reverse connection protection circuit 003 controls the second internal circuit 005 to stop functioning.

In the automotive-grade chip illustrated in FIG. 7, in the case that the power supply is reversely connected, a voltage (VSPI) at the SPI, a voltage at the first port, and a voltage at the SDO port are all equal to the reverse connection voltage (that is, the high voltage). In this case, the first reverse connection protection circuit 001 cuts off the pathway between the SPI and the first internal circuit 004, and cuts off the pathway between the SPI and the second internal circuit 005. The second reverse connection protection circuit 002 cuts off the pathway between the first port and the first internal circuit 004. The third reverse connection protection circuit 003 controls the second internal circuit 005 to stop functioning. This prevents the internal circuit assembly from operating under the high voltage, prevents the internal circuit assembly from damages, and enhances the reliability of the automotive-grade chip.

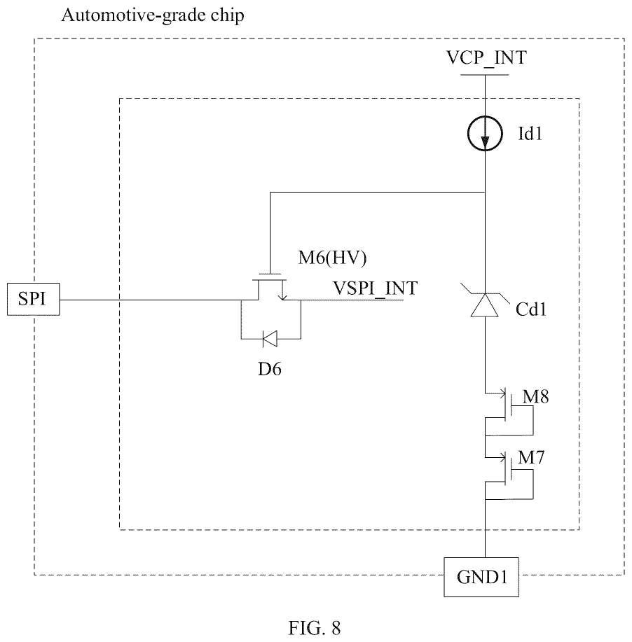

FIG. 8 is a schematic structural diagram of a first reverse connection protection circuit according to some embodiments of the present disclosure. As illustrated in FIG. 8, the first reverse connection protection circuit 001 includes a first high-voltage transistor M6, a first low-voltage transistor M7, a second low-voltage transistor M8, and a first clamp diode Cd1, and a first current source Id1.

A first terminal of the first high-voltage transistor M6 is electrically connected to the serial peripheral interface, a second terminal of the first high-voltage transistor M6 is electrically connected to the first internal circuit 004, the second internal circuit 005, and the third reverse connection protection circuit 003, a first terminal of the first current source Id1 is connected to a charge pump output voltage VCP_INT of the automotive-grade chip, a second terminal of the first current source Id1 is electrically connected to a cathode of the first clamp diode Cd1, an anode of the first clamp diode Cd1 is electrically connected to a second terminal of the second low-voltage transistor M8, a first terminal of the second low-voltage transistor M8 is electrically connected to a second terminal of the first low-voltage transistor M7, a first terminal of the first low-voltage transistor M7 is electrically connected to a ground port GND1 of the automotive-grade chip, a control terminal of the first high-voltage transistor M6 is electrically connected between the second terminal of the first current source Id1 and the cathode of the first clamp diode Cd1, a control terminal of the second low-voltage transistor M8 is electrically connected between the first terminal of the second low-voltage transistor M8 and the second terminal of the first low-voltage transistor M7, and a control terminal of the first low-voltage transistor M7 is electrically connected between the first terminal of the first low-voltage transistor M7 and the ground port GND1 of the automotive-grade chip.

In a possible design, a voltage rating of the first high-voltage transistor M6 is higher than the aforementioned high voltage, and voltage ratings of the first low-voltage transistor M7 and the second low-voltage transistor M8 are both higher than a 5 V low voltage.

In another possible design, the first high-voltage transistor M6 is an N-type metal-oxide-semiconductor field-effect transistor (NMOSFETs), and the first low-voltage transistor M7 and the second low-voltage transistor M8 are P-type metal-oxide-semiconductor field-effect transistors (PMOSFETs). The control terminal of the first high-voltage transistor M6 is a gate electrode G, the first terminal of the first high-voltage transistor M6 is a drain electrode D, and the second terminal of the first high-voltage transistor M6 is a source electrode S. The control terminal of the first low-voltage transistor M7 is a gate electrode G, the first terminal of the first low-voltage transistor M7 is a drain electrode D, and the second terminal of the first low-voltage transistor M7 is a source electrode S. The control terminal of the second low-voltage transistor M8 is a gate electrode G, the first terminal of the second low-voltage transistor M8 is a drain electrode D, and the second terminal of the second low-voltage transistor M8 is a source electrode S.

Based on the electrical connections illustrated in FIG. 8, the operating principle of the first reverse connection protection circuit 001 is as follows:

Based on FIG. 4 or FIG. 5, in the case that the power supply is reversely connected, the voltage at the power port BAT2 of the PCB is 0 V, and a high voltage (that is reverse connection voltage) is present at the ground port GND2 of the PCB. Due to the presence of the first reverse connection protection diode D2 or the protection circuit 006 between the ground port GND2 of the PCB and the ground port GND1 of the automotive-grade chip, the voltage at the ground port GND1 of the automotive-grade chip is 0 V. In this case, the charge pump output voltage VCP_INT is equal to 0 V, and fails provide a current to the first high-voltage transistor M6 to raise a voltage at the control terminal of the first high-voltage transistor M6. Therefore, the first high-voltage transistor M6 is turned off, and the SPI is electrically connected to the first internal circuit 004, the second internal circuit 005, and the third reverse connection protection circuit 003 via a body diode D6 of the first high-voltage transistor M6. That is, the SPI is reversely electrically connected to the first internal circuit 004, the second internal circuit 005, and the third reverse connection protection circuit 003 via the body diode D6. Since the serial peripheral interface is reversely electrically connected to the first internal circuit 004, the second internal circuit 005, and the third reverse connection protection circuit 003 via the body diode D6, in the case that the voltage at the SPI is equal to the reverse connection voltage (that is, high voltage), the first internal circuit 004 and the second internal circuit 005 are be protected from damages.

Based on FIG. 5, in the case that the power supply is positively connected, a high voltage is present at the power port BAT2 of the PCB, the voltage at the ground port GND2 of the PCB is 0 V, and the LDO provides a voltage VSPI via the SPI and outputs a low voltage via the LDO. The charge pump output voltage VCP_INT provides a current to the first clamp diode Cd1, the second low-voltage transistor M8, and the first low-voltage transistor M7. The voltage at the control terminal of the first high-voltage transistor M6 is: VG6=VCd1+|VGS7|+|VGS8|, wherein VCd1 represents the clamp voltage of the first clamp diode Cd1, |VGS7| represents an absolute value of the voltage difference between the control terminal and the second terminal of the first low-voltage transistor M7, and |VGS8| represents an absolute value of the voltage difference between the control terminal and the second terminal of the second low-voltage transistor M8. By adjusting the parameters, the voltage VGS6 between the control terminal and the second terminal of the first high-voltage transistor M6 is approximately equal to the clamp voltage of the first clamp diode Cd1, such that the first high-voltage transistor M6 is controlled to be turned on. Since the voltage drop is typically only a few mV in the case that the first high-voltage transistor M6 is turned on, which is far less than a voltage drop across the reverse connection protection diode, the voltage of the internal power supply in the automotive-grade chip is prevented from being excessively reduced and the cold-start performance of the automotive-grade chip is improved.

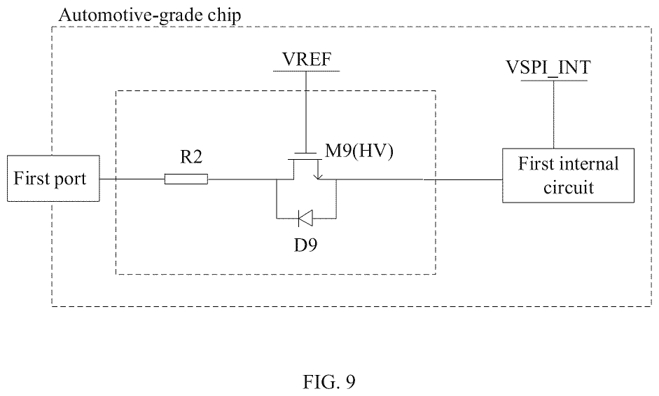

FIG. 9 is a schematic structural diagram of a second reverse connection protection circuit according to some embodiments of the present disclosure. As illustrated in FIG. 9, the second reverse connection protection circuit 002 includes: a first resistor R2 and a second high-voltage transistor M9.

A first terminal of the first resistor R2 is electrically connected to the first port, a second terminal of the first resistor R2 is electrically connected to a first terminal of the second high-voltage transistor M9, a second terminal of the second high-voltage transistor M9 is electrically connected to a second input terminal of the first internal circuit 004, and a control terminal of the second high-voltage transistor M9 is connected to a reference voltage VREF.

The first resistor R2 is a current-limiting resistor.

The second high-voltage transistor M9, for example, is an NMOS transistor. The control terminal of the second high-voltage transistor M9 is a gate electrode G, the first terminal of the second high-voltage transistor M9 is a drain electrode D, and the second terminal of the second high-voltage transistor M9 is a source electrode S.

In a possible design, a voltage rating of the second high-voltage transistor M9 is higher than the aforementioned high voltage.

In a possible design, in the case that the power supply is positively connected, for example, the high voltage is equal to 14 V, the reference voltage VREF may be equal to 9 V. In the case that the power supply is reversely connected, the reference voltage VREF may be equal to 0 V.

Based on the electrical connection illustrated in FIG. 9, the operating principle of the second reverse connection protection circuit 002 is as follows:

Based on FIG. 4 or FIG. 5, in the case that the power supply is reversely connected, the voltage at the power port BAT2 of the PCB is 0 V, and a high voltage is present at the ground port GND2 of the PCB. Due to the presence of the first reverse connection protection diode D2 or the protection circuit 006 between the ground port GND2 of the PCB and the ground port GND1 of the automotive-grade chip, the voltage at the ground port GND1 of the automotive-grade chip is 0 V. In the case that the power supply is reversely connected, the reference voltage VREF is equal to 0 V and the voltage at the control terminal of the second high-voltage transistor M9 fails to be raised. Therefore, the second high-voltage transistor M9 is turned off, and the first port is electrically connected to the first internal circuit 004 via the body diode D9 of the second high-voltage transistor M9. That is, the first port is reversely electrically connected to the first internal circuit 004 via the body diode D9. Since the first port is reversely electrically connected to the first internal circuit 004 via the body diode D9, in the case that the voltage at the first terminal is equal to the reverse connection voltage (that is, high voltage), the first internal circuit 004 may be protected from damages.

Based on FIG. 5, in the case that the power supply is positively connected, a high voltage is present at the power port BAT2 of the PCB, the voltage at the ground port GND2 of the PCB is 0 V, the voltage at the first terminal is equal to 5 V, the reference voltage VREF is equal to 9 V, and the second high-voltage transistor M9 is turned on. Since the voltage drop is typically only a few mV in the case that the second high-voltage transistor M9 is turned on, which is far less than a voltage drop across the reverse connection protection diode, the voltage of the internal power supply in the automotive-grade chip is prevented from being excessively reduced and the cold-start performance of the automotive-grade chip is improved.

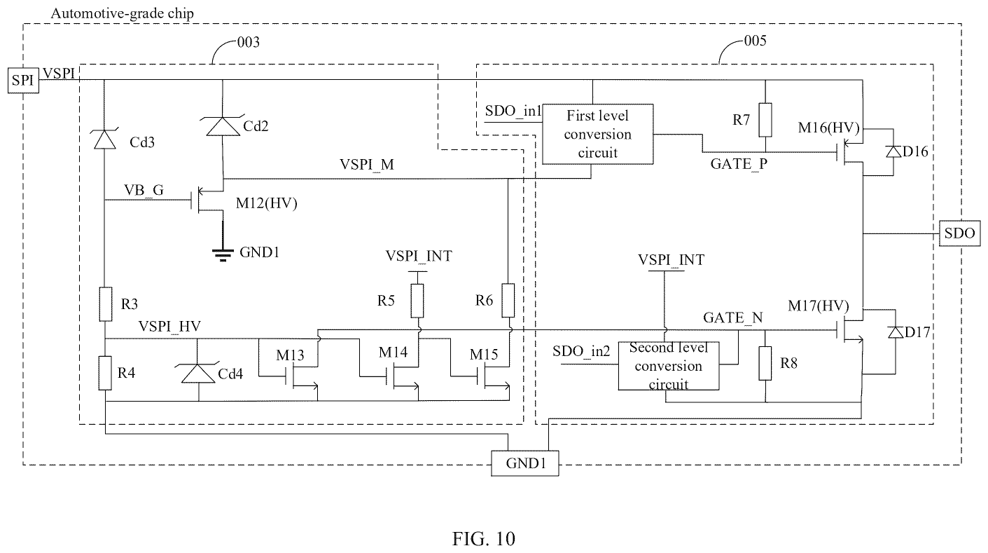

FIG. 10 is a schematic structural diagram of a third reverse connection protection circuit according to some embodiments of the present disclosure. As illustrated in FIG. 10, the third reverse connection protection circuit 003 includes: a second clamp diode Cd2, a third clamp diode Cd3, a fourth clamp diode Cd4, a second resistor R3, a third resistor R4, a fourth resistor R5, a fifth resistor R6, a third high-voltage transistor M12, a third low-voltage transistor M13, a fourth low-voltage transistor M14, and a fifth low-voltage transistor M15.

The SPI is electrically connected to the second internal circuit 005, a cathode of the third clamp diode Cd3 is electrically connected between the SPI and the second internal circuit 005, an anode of the third clamp diode Cd3 is electrically connected to a first terminal of the second resistor R3, a second terminal of the second resistor R3 is electrically connected to a first terminal of the third resistor R4, and a second terminal of the third resistor R4 is electrically connected to a ground port GND1 of the automotive-grade chip.

A cathode of the second clamp diode Cd2 is electrically connected between the SPI and the second internal circuit 005, an anode of the second clamp diode Cd2 is electrically connected to a second terminal of the third high-voltage transistor M12, a first terminal of the third high-voltage transistor M12 is electrically connected to the ground port of the automotive-grade chip, a control terminal of the third high-voltage transistor M12 is electrically connected between the anode of the third clamp diode Cd3 and the first terminal of the second resistor R3, and the second internal circuit 005 is further electrically connected between the anode of the second clamp diode Cd2 and the second terminal of the third high-voltage transistor M12.

A cathode of the fourth clamp diode Cd4, a control terminal of the third low-voltage transistor M13, and a control terminal of the fourth low-voltage transistor M14 are all electrically connected between the second terminal of the second resistor R3 and the first terminal of the third resistor R4, an anode of the fourth clamp diode Cd4, a second terminal of the third low-voltage transistor M13, a second terminal of the fourth low-voltage transistor M14, and a second terminal of the fifth low-voltage transistor M15 are all electrically connected between the second terminal of the third resistor R4 and the ground port GND1 of the automotive-grade chip, a first terminal of the third low-voltage transistor M13 is electrically connected to the second internal circuit 005, a first terminal of the fourth low-voltage transistor M14 is electrically connected to the first reverse connection protection circuit 001 via the fourth resistor R5, a control terminal of the fifth low-voltage transistor M15 is electrically connected between the first terminal of the fourth low-voltage transistor M14 and the fourth resistor R5, and a first terminal of the fifth low-voltage transistor M15 is electrically connected between the second internal circuit 005 and the second terminal of the third high-voltage transistor M12 via the fifth resistor R6.

The second internal circuit 005 includes a first level conversion circuit, a second level conversion circuit, a sixth resistor R7, a seventh resistor R8, a fifth high-voltage transistor M16, and a sixth high-voltage transistor M17. The sixth resistor R7 is a pull-up resistor of a control terminal of the fifth high-voltage transistor M16, and the seventh resistor R8 is a control terminal pull-down resistor of a control terminal of the sixth high-voltage transistor M17. A voltage at a control terminal of the fifth high-voltage transistor M16 is GATE_P, and a voltage at a control terminal of the sixth high-voltage transistor M17 is GATE_N. The voltage GATE_P is a voltage generated by the first level conversion circuit based on a first internal signal SDO_in1. The voltage GATE_N is a voltage generated by the second level conversion circuit based on a second internal signal SDO_in2.

The output signal of the SDO is controlled by the fifth high-voltage transistor M16 and the sixth high-voltage transistor M17.

In a possible design, the third high-voltage transistor M12 and the fifth high-voltage transistor M16 are all PMOS transistors, and the third low-voltage transistor M13, the fourth low-voltage transistor M14, the fifth low-voltage transistor M15, and the sixth high-voltage transistor M17 are all NMOS transistors.

The control terminal of the third high-voltage transistor M12 is a gate electrode G, the first terminal of the third high-voltage transistor M12 is a drain electrode D, and the second terminal of the third high-voltage transistor M12 is the source electrode S.

The control terminal of the third low-voltage transistor M13, the control terminal of the fourth low-voltage transistor M14, and the control terminal of the fifth low-voltage transistor M15 are all the gate electrode G, and the first terminal of the third low-voltage transistor M13, the first terminal of the fourth low-voltage transistor M14, and the first terminal of the fifth low-voltage transistor M15 are all the drain electrode D, and the second terminal of the third low-voltage transistor M13, the second terminal of the fourth low-voltage transistor M14, and the second terminal of the fifth low-voltage transistor M15 are all the source electrode S.

The control terminal of the fifth high-voltage transistor M16 and the control terminal of the sixth high-voltage transistor M17 are both the gate electrodes G.

In a possible design, the voltage ratings of the third high-voltage transistor M12, the fifth high-voltage transistor M16, and the sixth high-voltage transistor M17 are all higher than the aforementioned high voltage, and the voltage ratings of the third low-voltage transistor M13, the fourth low-voltage transistor M14, and the fifth low-voltage transistor M15 are all higher than the 5 V low voltage.

The electrical connections of the first level conversion circuit, the second level conversion circuit, the sixth resistor R7, the seventh resistor R8, the fifth high-voltage transistor M16, and the sixth high-voltage transistor M17 is illustrated in FIG. 10, which are not described herein any further.

Based on the electrical connections illustrated in FIG. 10, the operating principle of the third reverse connection protection circuit 003 is as follows:

Based on FIG. 4 or FIG. 5, in the case that the power supply is reversely connected, the voltage at the power port BAT2 of the PCB is 0 V, and a high voltage is present at the ground port GND2 of the PCB. Due to the presence of the first reverse connection protection diode D2 or the protection circuit 006 between the ground port GND2 of the PCB and the ground port GND1 of the automotive-grade chip, the voltage at the ground port GND1 of the automotive-grade chip is equal to 0 V. The voltage VSPI_INT is no longer provided by the SPI, and the voltage VSPI on the SPI is equal to high voltage. The clamp voltage of the third clamp diode Cd3 is lower than the voltage VSPI. A voltage VB_G at the control terminal of the third high-voltage transistor M12 rises, which causes a current to flow through the second resistor R3 and the third resistor R4, and then causes the voltage VSPI_HV at the control terminal of the third low-voltage transistor M13 and the control terminal of the fourth low-voltage transistor M14 to rise. The fourth clamp diode Cd4 controls the voltage VSPI_HV to be equal to the clamp voltage of the fourth clamp diode Cd4. The third low-voltage transistor M13 is turned on to pull the voltage at the control terminal GATE_N of the sixth high-voltage transistor M17 down to 0 V, and the voltage GATE_N is no longer controlled by the second internal signal SDO_in2. Therefore, the sixth high-voltage transistor M17 is turned off. The fourth low-voltage transistor M14 is turned on to pull the voltage VSPI_INT and the voltage at the control terminal of the fifth low-voltage transistor M15 down to 0 V. The fifth low-voltage transistor M15 pulls down the voltage VSPI_INT and the voltage at control terminal of the fifth low-voltage transistor M15 to 0 V, the fifth low-voltage transistor M15 is turned off and the voltage VSPI_M is pulled down. In this case, VSPI_M=VSPI−VCd3+|VGS12|, wherein VCd3 represents the clamp voltage of the third clamp diode Cd3, and |VGS12| represents the absolute value of the voltage difference between the control terminal and the second terminal of the third high-voltage transistor M12. The second clamp diode Cd2 clamps the voltage difference between VSPI and VSPI_M, to ensure that the low-voltage components inside the first level conversion circuit operates safely between VSPI and VSPI_M. Both the first internal signal SDO_in1 and the second internal signal SDO_in2 are low potential voltages. The GATE_P, after being processed by the first level conversion circuit, is equal to the VSPI. Therefore, the fifth high-voltage transistor M16 is turned off. Since both the sixth high-voltage transistor M17 and the fifth high-voltage transistor M16 are turned off, the second internal circuit 005 stops functioning. It should be noted that in the case that the fifth high-voltage transistor M16 is turned off, the SPI is electrically connected to the SDO port via the body diode D16 of the fifth high-voltage transistor M16; and in the case that the voltage at the SDO port is equal to VSPI, the voltage at two terminals of the body diode D16 are the same. In the case that the sixth high-voltage transistor M17 is turned off, the ground port GND1 of the automotive-grade chip is electrically connected to the SDO port via the body diode D17 of the sixth high-voltage transistor M17. In the case that the voltage at the SDO port is equal to VSPI, the body diode D17 protects the ground port GND1 to prevent the voltage at the SDO port from affecting the ground port GND1.

Based on FIG. 5, in the case that the power supply is positively connected, a high voltage is present at the power port BAT2 of the PCB, the voltage at the ground port GND2 of the PCB is 0 V, and the voltages VSPI and VSPI_INT are both 5 V. Since the clamp voltage of the third clamp diode Cd3 is higher than the voltage VSPI, an anode voltage VB_G of the third clamp diode Cd3 and a cathode voltage VSPI_HV of the fourth clamp diode Cd4 are equal and close to 0 V. The third low-voltage transistor M13 and the fourth low-voltage transistor M14 are turned off, and the voltage VSPI_INT provides a voltage to the fifth low-voltage transistor M15 via the fourth resistor R5, such that the fifth low-voltage transistor M15 is turned on, and hence the voltage VSPI_M is pulled to 0 V and both the voltages GATE_P and GATE_N are 0 V. In this way, the sixth high-voltage transistor M17 is turned off, and the fifth high-voltage transistor M16 is turned on.

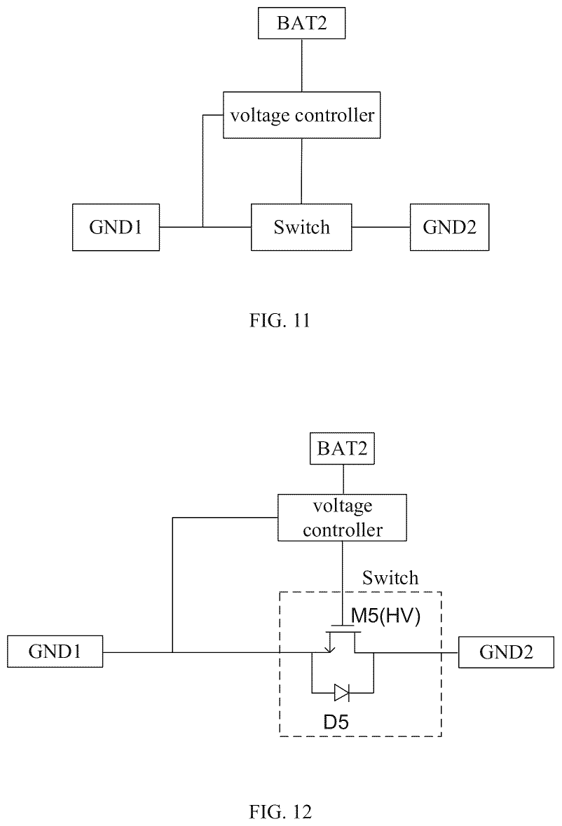

FIG. 11 is a schematic structural diagram of a protection circuit 006 according to some embodiments of the present disclosure. As illustrated in FIG. 11, the protection circuit 006 includes a switch and a voltage controller.

A first terminal of the switch is electrically connected to the ground port GND2 of the PCB, a second terminal of the switch is electrically connected to the ground port GND1 of the automotive-grade chip, a control terminal of the switch is electrically connected to a first terminal of the voltage controller, a second terminal of the voltage controller is electrically connected between the second terminal of the switch and the ground port GND1 of the automotive-grade chip, and a third terminal of the voltage controller is electrically connected to the power port of the PCB. The automotive-grade chip, the switch, the voltage controller, and the protection circuit 006 are arranged on the PCB.

The voltage controller is configured to control the switch to turn on or turn off.

Based on an electrical connection illustrated in FIG. 11, in the case that the voltage at the power port of the PCB is less than the reverse connection voltage (that is, high voltage) (that is, the power supply is reversely connected), the voltage controller controls the switch to turn off to cut off a pathway between the ground port GND2 of the PCB and the ground port GND1 of the automotive-grade chip; or in the case that the voltage at the power port BAT2 of the PCB is equal to the reverse connection voltage (that is, the power supply is positively connected), the voltage controller controls the switch to turn on to conduct the pathway between the ground port GND2 of the PCB and the ground port GND1 of the automotive-grade chip. A voltage drop in the case that the switch is turned on is less than a predetermined voltage threshold.

In some possible designs, the predetermined voltage threshold may be equal to the voltage drop of the reverse connection protection diode in the case that the power supply is reversely connected.

In some possible designs, the voltage drop can be 5 millivolts (m V) or 6 mV, or the like in the case that the switch is turned on.

In the embodiments of the present disclosure, in the case that the power supply is reversely connected, the voltage controller controls the switch to turn off to cut off the pathway between the ground port GND2 of the PCB and the ground port GND1 of the automotive-grade chip. This prevents the internal circuit assembly from operating under high voltages, protects the internal circuit assembly from damages, and enhances the reliability of the automotive-grade chip. In the case that the power supply is positively connected, the voltage controller controls the switch to turn on to conduct the pathway between the ground port GND2 of the PCB and the ground port GND1 of the automotive-grade chip. Since the voltage drop is less than the predetermined voltage threshold in the case that the switch is turned on, the cold-start performance of the automotive-grade chip is improved.

FIG. 12 is a schematic structural diagram of a switch according to some embodiments of the present disclosure. Based on FIG. 11, as illustrated in FIG. 12, the switch includes a fourth high-voltage transistor M5.

A first terminal of the fourth high-voltage transistor M5 is electrically connected to the ground port GND2 of the PCB. A second terminal of the fourth high-voltage transistor M5 is electrically connected to the ground port GND1 of the automotive-grade chip, and a control terminal of the fourth high-voltage transistor M5 is electrically connected to the first terminal of the voltage controller.

In a possible design, the fourth high-voltage transistor M5 is an NMOS transistor. The control terminal of the fourth high-voltage transistor M5 is a gate electrode G, the first terminal of the fourth high-voltage transistor M5 is a drain electrode D, and the second terminal of the fourth high-voltage transistor M5 is a source electrode S.

In a possible design, a voltage rating of the fourth high-voltage transistor M5 is higher than the aforementioned high voltage.

A voltage drop is equal to a voltage VDS5 between a first terminal and a second terminal of the fourth high-voltage transistor M5 in the case that the fourth high-voltage transistor M5 is turned on, wherein VDS5=Is*Rdson, Is represents an average current value of an entire automotive-grade chip, and Rdson represents an on-resistance of the fourth high-voltage transistor M5.

The voltage drop is less than a predetermined voltage threshold in the case that the fourth high-voltage transistor M5 is turned on.

In the case that the power supply is positively connected, the fourth high-voltage transistor M5 is turned on, and the voltage drop across the fourth high-voltage transistor M5 is typically only several mV, which is far less than a voltage drop across the reverse connection protection diode. This prevents excessive internal power supply voltage reduction in the automotive-grade chip and improves the cold-start performance of the automotive-grade chip.

In the case that the power supply is reversely connected, the fourth high-voltage transistor M5 is turned off, and the ground port GND2 of the PCB is electrically connected to the ground port GND1 of the automotive-grade chip via a body diode D5 of the fourth high-voltage transistor M5. In the case that ground port GND2 of the PCB has a high voltage, the ground port GND1 is prevented from being a high voltage via the body diode D5.

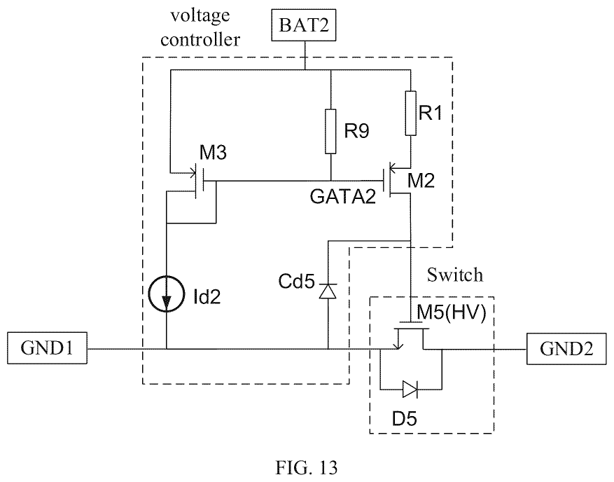

FIG. 13 is a schematic structural diagram of a voltage controller according to some embodiments of the present disclosure. Based on FIG. 12, as illustrated in FIG. 13, the voltage controller includes: a seventh high-voltage transistor M3, a fifth resistor R1, an eighth resistor R9, an eighth high-voltage transistor M2, a fifth clamp diode Cd5, and a second current source Id2.

A second terminal of the seventh high-voltage transistor M3, a first terminal of the fifth resistor R1, and a first terminal of the eighth resistor R9 are all electrically connected to the power port of the PCB, a control terminal of the seventh high-voltage transistor M3 is electrically connected to a control terminal of the eighth high-voltage transistor M2, a second terminal of the eighth resistor R9 is electrically connected between the control terminal of the seventh high-voltage transistor M3 and the control terminal of the eighth high-voltage transistor M2, a second terminal of the fifth resistor R1 is electrically connected to a second terminal of the eighth high-voltage transistor M2, a first terminal of the eighth high-voltage transistor M2 is electrically connected to the control terminal of the fourth high-voltage transistor M5, the first terminal of the fourth high-voltage transistor M5 is electrically connected to the ground port GND2 of the PCB, the second terminal of the fourth high-voltage transistor M5 is electrically connected to the ground port GND1 of the automotive-grade chip, a cathode of the fifth clamp diode Cd5 is electrically connected between the first terminal of the eighth high-voltage transistor M2 and the control terminal of the fourth high-voltage transistor M5, an anode of the fifth clamp diode Cd5 is electrically connected between the second terminal of the fourth high-voltage transistor M5 and the ground port GND1 of the automotive-grade chip, and a first terminal of the seventh high-voltage transistor M3 is connected between the second terminal of the fourth high-voltage transistor M5 and the ground port GND1 of the automotive-grade chip via the second current source Id2.

In a possible design, the seventh high-voltage transistor M3 and the eighth high-voltage transistor M2 are both PMOS transistors. The fourth high-voltage transistor M5 is an NMOS transistor. The control terminal of the seventh high-voltage transistor M3 is a gate electrode G, the first terminal of the seventh high-voltage transistor M3 is a drain electrode D, and the second terminal of the seventh high-voltage transistor M3 is a source electrode S. The control terminal of the eighth high-voltage transistor M2 is a gate electrode G, the first terminal of the eighth high-voltage transistor M2 is a drain electrode D, and the second terminal of the eighth high-voltage transistor M2 is a source electrode S. The control terminal of the fourth high-voltage transistor M5 is a gate electrode G, the first terminal of the fourth high-voltage transistor M5 is a drain electrode D, and the second terminal of the fourth high-voltage transistor M5 is a source electrode S.

In a possible design, voltage ratings of the seventh high-voltage transistor M3 and the eighth high-voltage transistor M2 are both higher than the aforementioned high voltage.

Based on the electrical connections illustrated in FIG. 13, the operating principle of the voltage controller is as follows:

In the case that the power supply is positively connected, the second current source Id2 generates a current that flows through the seventh high-voltage transistor M3, the eighth high-voltage transistor M2 and the seventh high-voltage transistor M3 form a current mirror, the fifth resistor R1 serves as a current-limiting resistor and is configured to prevent excessive current, and the eighth high-voltage transistor M2 generates a current that flows through the fifth clamp diode Cd5. In this case, a voltage VGS5 between the control terminal and the second terminal of the fourth high-voltage transistor M5 is equal to a clamp voltage of the fifth clamp diode Cd5 (usually around 6 V), such that the fourth high-voltage transistor M5 is turned on.

In the case that the power supply is reversely connected, BAT2 is considered as a ground potential, the second current source Id2 no longer generates a current that flows through the seventh high-voltage transistor M3, the eighth resistor R9 connects the control terminal of the eighth high-voltage transistor M2 to the ground potential, the eighth high-voltage transistor M2 no longer generates a current that flows through the fifth clamp diode Cd5. In this case, the voltage VGS5 between the control terminal and the second terminal of the fourth high-voltage transistor M5 is equal to the clamp voltage of the fifth clamp diode Cd5 (near zero potential), such that the fourth high-voltage transistor M5 is turned off.

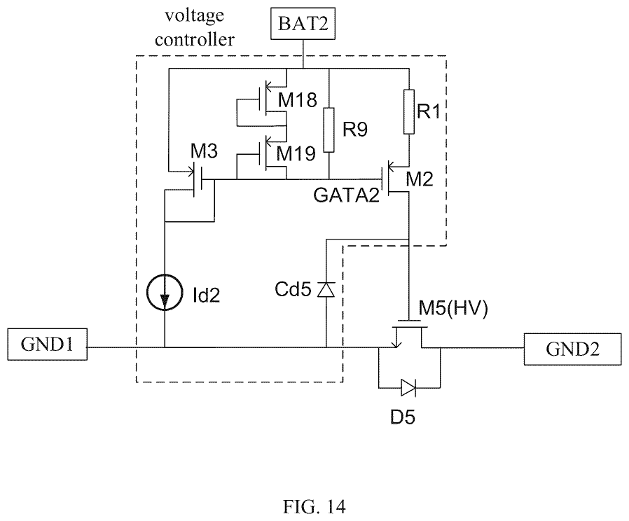

FIG. 14 is a schematic structural diagram of a voltage controller according to some embodiments of the present disclosure. Based on FIG. 13, as illustrated in FIG. 14, the voltage controller further includes: a sixth low-voltage transistor M18 and a seventh low-voltage transistor M19.

A second terminal of the sixth low-voltage transistor M18 is electrically connected to the power port BAT2 of the PCB, a first terminal of the sixth low-voltage transistor M18 is electrically connected to a second terminal of the seventh low-voltage transistor M19, a control terminal of the sixth low-voltage transistor M18 is electrically connected between the first terminal of the sixth low-voltage transistor M18 and the second terminal of the seventh low-voltage transistor M19, and a first terminal of the seventh low-voltage transistor M19 and the a control terminal of the seventh low-voltage transistor M19 are both electrically connected between the control terminal of the seventh high-voltage transistor M3 and the control terminal of the eighth high-voltage transistor M2.

In a possible design, the sixth low-voltage transistor M18 and the seventh low-voltage transistor M19 are PMOS transistors. The control terminal of the sixth low-voltage transistor M18 is a gate electrode G, the first terminal of the sixth low-voltage transistor M18 is a drain electrode D, and the second terminal of the sixth low-voltage transistor M18 is a source electrode S. The control terminal of the seventh low-voltage transistor M19 is a gate electrode G, the first terminal of the seventh low-voltage transistor M19 is a drain electrode D, and the second terminal of the seventh low-voltage transistor M19 is a source electrode S.

In a possible design, voltage ratings of the sixth low-voltage transistor 18 and the seventh high-voltage transistor M19 are both higher than the aforementioned 5 V low voltage.

The sixth low-voltage transistor M18 and the seventh low-voltage transistor M19 are configured to clamp a voltage difference between the voltage at the power port BAT2 of the PCB and the voltage at the control terminal of the eighth high-voltage transistor M2. This prevents the voltage difference between the voltage at the power port BAT2 and the voltage at the control terminal of the eighth high-voltage transistor M2 from becoming too large.

In the embodiments of the present disclosure, the sixth low-voltage transistor M18 and the seventh low-voltage transistor M19 prevent the voltage difference between the voltage at the power port BAT2 and the voltage at the control terminal of the eighth high-voltage transistor M2 from becoming too large, thereby avoiding damages to the seventh high-voltage transistor M3 and the eighth high-voltage transistor M2 due to their respective gate-source voltages (VGS) being too high. In this way, the safety of both the seventh high-voltage transistor M3 and the eighth high-voltage transistor M2 is enhanced.

The units which are described as separate units or modules may be physically separated or may be not physically separated, and the components which are illustrated as units may be or may not be physical units or modules, that is, the components may be located in the same position or may be distributed into a plurality of units or modules. Part or all of the units or modules may be selected according to the actual needs to achieve the objects of the technical solutions of the embodiments.

In the several embodiments provided in the present disclosure, it should be understood that the division of the above-mentioned units or modules is merely a logical functional division, and other division methods may be used in actual implementation. For example, various functional units in the embodiments of the present disclosure may be integrated into one unit, or each of the units may exist along physically, or two or more units may be integrated into one unit. Still for example, functional modules in the embodiments of the present disclosure may be integrated into one module, or each of the modules may exist along physically, or two or more modules may be integrated into one module.

Finally, it should be noted that the above embodiments are merely used to illustrate the technical solutions according to the embodiments of the present disclosure rather than limiting the technical solutions according to the embodiments of the present disclosure. Although according to the embodiments of the present disclosure are described in detail with reference to the foregoing embodiments, persons of ordinary skill in the art should understand that they may still make modifications to the technical solutions according to the embodiments, or make equivalent replacements to some of the technical features, However, such modifications or replacements do not cause the essence of the corresponding technical solutions to depart from the spirit and scope of the technical solutions of the embodiments of the present disclosure. Therefore, the protection scope according to the embodiments of the present disclosure is subject to the appended claims.

1. An automotive-grade chip, comprising: a plurality of reverse connection protection circuits, a plurality of ports corresponding to the plurality of reverse connection protection circuits respectively, and an internal circuit assembly; wherein
a reverse connection protection circuit of the plurality of reverse connection protection circuits is electrically connected between a port corresponding to the reverse connection protection circuit and the internal circuit assembly, and the port is further electrically connected to a controller or electrically connected between a controller and a low dropout linear regulator; and
the reverse connection protection circuit is configured to, in a case that a voltage at the port corresponding to the reverse connection protection circuit is equal to a reverse connection voltage of the controller, cut off a pathway between the port and the internal circuit assembly and/or control the internal circuit assembly to stop functioning.

2. The automotive-grade chip according to claim 1, wherein the plurality of reverse connection protection circuits comprise: a first reverse connection protection circuit, a second reverse connection protection circuit, and a third reverse connection protection circuit; wherein
a port corresponding to the first reverse connection protection circuit is a serial peripheral interface, a port corresponding to the second reverse connection protection circuit is a first port, and a port corresponding to the third reverse connection protection circuit is a serial data output port; and
the internal circuit assembly comprises a first internal circuit and a second internal circuit; wherein
the first reverse connection protection circuit is electrically connected to the first internal circuit, the second internal circuit, and the third reverse connection protection circuit, the second reverse connection protection circuit is electrically connected between the first port and the first internal circuit, the third reverse connection protection circuit is electrically connected between the serial data output port and the second internal circuit, and the third reverse connection protection circuit is further electrically connected to the serial peripheral interface;
the first reverse connection protection circuit is configured to, in a case that a voltage at the serial peripheral interface is equal to the reverse connection voltage, cut off a pathway between the serial peripheral interface and the first internal circuit, cut off a pathway between the serial peripheral interface and the second internal circuit, and cut off a pathway between the serial peripheral interface and the third reverse connection protection circuit;
the second reverse connection protection circuit is configured to, in response to a voltage at the first port being equal to the reverse connection voltage, cut off a pathway between the first port and the first internal circuit; and
the third reverse connection protection circuit is configured to, in response to a voltage at the serial data output port being equal to the reverse connection voltage, control the second internal circuit to stop functioning.

3. The automotive-grade chip according to claim 2, wherein the first reverse connection protection circuit comprises: a first high-voltage transistor, a first low-voltage transistor, a second low-voltage transistor, and a first clamp diode, and a first current source; wherein
a first terminal of the first high-voltage transistor is electrically connected to the serial peripheral interface, a second terminal of the first high-voltage transistor is electrically connected to the first internal circuit, the second internal circuit, and the third reverse connection protection circuit, a first terminal of the first current source is connected to a charge pump output voltage of the automotive-grade chip, a second terminal of the first current source is electrically connected to a cathode of the first clamp diode, an anode of the first clamp diode is electrically connected to a second terminal of the second low-voltage transistor, a first terminal of the second low-voltage transistor is electrically connected to a second terminal of the first low-voltage transistor, a first terminal of the first low-voltage transistor is electrically connected to a ground port of the automotive-grade chip, a control terminal of the first high-voltage transistor is electrically connected between the second terminal of the first current source and the cathode of the first clamp diode, a control terminal of the second low-voltage transistor is electrically connected between the first terminal of the second low-voltage transistor and the second terminal of the first low-voltage transistor, and a control terminal of the first low-voltage transistor is electrically connected between the first terminal of the first low-voltage transistor and the ground port of the automotive-grade chip.

4. The automotive-grade chip according to claim 2, wherein the second reverse connection protection circuit comprises: a first resistor and a second high-voltage transistor;
wherein a first terminal of the first resistor is electrically connected to the first port, a second terminal of the first resistor is electrically connected to a first terminal of the second high-voltage transistor, a second terminal of the second high-voltage transistor is electrically connected to a second input terminal of the first internal circuit, and a control terminal of the second high-voltage transistor is connected to a reference voltage.

5. The automotive-grade chip according to claim 2, wherein the first port comprises at least one of a serial clock port and a serial data input port.

6. The automotive-grade chip according to claim 2, wherein the third reverse connection protection circuit comprises: a second clamp diode, a third clamp diode, a fourth clamp diode, a second resistor, a third resistor, a fourth resistor, a fifth resistor, a third high-voltage transistor, a third low-voltage transistor, a fourth low-voltage transistor, and a fifth low-voltage transistor; wherein
the serial peripheral interface is electrically connected to the second internal circuit, a cathode of the third clamp diode is electrically connected between the serial peripheral interface and the second internal circuit, an anode of the third clamp diode is electrically connected to a first terminal of the second resistor, a second terminal of the second resistor is electrically connected to a first terminal of the third resistor, and a second terminal of the third resistor is electrically connected to a ground port of the automotive-grade chip;
a cathode of the second clamp diode is electrically connected between the serial peripheral interface and the second internal circuit, an anode of the second clamp diode is electrically connected to a second terminal of the third high-voltage transistor, a first terminal of the third high-voltage transistor is electrically connected to the ground port of the automotive-grade chip, a control terminal of the third high-voltage transistor is electrically connected between the anode of the third clamp diode and the first terminal of the second resistor, and the second internal circuit is further electrically connected between the anode of the second clamp diode and the second terminal of the third high-voltage transistor; and
a cathode of the fourth clamp diode, a control terminal of the third low-voltage transistor, and a control terminal of the fourth low-voltage transistor are all electrically connected between the second terminal of the second resistor and the first terminal of the third resistor, an anode of the fourth clamp diode, a second terminal of the third low-voltage transistor, a second terminal of the fourth low-voltage transistor, and a second terminal of the fifth low-voltage transistor are all electrically connected between the second terminal of the third resistor and the ground port of the automotive-grade chip, a first terminal of the third low-voltage transistor is electrically connected to the second internal circuit, a first terminal of the fourth low-voltage transistor is electrically connected to the first reverse connection protection circuit via the fourth resistor, a control terminal of the fifth low-voltage transistor is electrically connected between the first terminal of the fourth low-voltage transistor and the fourth resistor, and a first terminal of the fifth low-voltage transistor is electrically connected between the second internal circuit and the second terminal of the third high-voltage transistor via the fifth resistor.

7. A protection circuit, comprising: an automotive-grade chip, a switch and a voltage controller; wherein the automotive-grade chip comprises a plurality of reverse connection protection circuits, a plurality of ports corresponding to the plurality of reverse connection protection circuits respectively, and an internal circuit assembly; wherein,
a reverse connection protection circuit of the plurality of reverse connection protection circuits is electrically connected between a port corresponding to the reverse connection protection circuit and the internal circuit assembly, and the port is further electrically connected to a controller or electrically connected between a controller and a low dropout linear regulator;
the reverse connection protection circuit is configured to, in a case that a voltage at the port corresponding to the reverse connection protection circuit is equal to a reverse connection voltage of the controller, cut off a pathway between the port and the internal circuit assembly and/or control the internal circuit assembly to stop functioning;
a first terminal of the switch is electrically connected to a ground port of a printed circuit board, a second terminal of the switch is electrically connected to a ground port of the automotive-grade chip, a control terminal of the switch is electrically connected to a first terminal of the voltage controller, a second terminal of the voltage controller is electrically connected between the second terminal of the switch and the ground port of the automotive-grade chip, and a third terminal of the voltage controller is electrically connected to a power port of the printed circuit board, wherein the automotive-grade chip, the switch, and the voltage controller are arranged on the printed circuit board; and
the voltage controller is configured to, in a case that a voltage at the power port of the printed circuit board is less than the reverse connection voltage, control the switch to turn off to cut off a pathway between the ground port of the printed circuit board and the ground port of the automotive-grade chip, and in a case that the voltage at the power port of the printed circuit board is equal to the reverse connection voltage, control the switch to turn on to conduct the pathway between the ground port of the printed circuit board and the ground port of the automotive-grade chip, wherein a voltage drop is less than a predetermined voltage threshold in a case that the switch is turned on.

8. The protection circuit according to claim 7, wherein the switch comprises: a fourth high-voltage transistor;
wherein a first terminal of the fourth high-voltage transistor is electrically connected to the ground port of the printed circuit board, a second terminal of the fourth high-voltage transistor is electrically connected to the ground port of the automotive-grade chip, and a control terminal of the fourth high-voltage transistor is electrically connected to the first terminal of the voltage controller.

9. The protection circuit according to claim 8, wherein the voltage controller comprises: a seventh high-voltage transistor, a fifth resistor, an eighth resistor, an eighth high-voltage transistor, a fifth clamp diode, and a second current source;
wherein a second terminal of the seventh high-voltage transistor, a first terminal of the fifth resistor, and a first terminal of the eighth resistor are all electrically connected to the power port of the printed circuit board, a control terminal of the seventh high-voltage transistor is electrically connected to a control terminal of the eighth high-voltage transistor, a second terminal of the eighth resistor is electrically connected between the control terminal of the seventh high-voltage transistor and the control terminal of the eighth high-voltage transistor, a second terminal of the fifth resistor is electrically connected to a second terminal of the eighth high-voltage transistor, a first terminal of the eighth high-voltage transistor is electrically connected to the control terminal of the fourth high-voltage transistor, the first terminal of the fourth high-voltage transistor is electrically connected to the ground port of the printed circuit board, the second terminal of the fourth high-voltage transistor is electrically connected to the ground port of the automotive-grade chip, a cathode of the fifth clamp diode is electrically connected between the first terminal of the eighth high-voltage transistor and the control terminal of the fourth high-voltage transistor, an anode of the fifth clamp diode is electrically connected between the second terminal of the fourth high-voltage transistor and the ground port of the automotive-grade chip, and a first terminal of the seventh high-voltage transistor is connected between the second terminal of the fourth high-voltage transistor and the ground port of the automotive-grade chip via the second current source.

10. The protection circuit according to claim 9, wherein the voltage controller further comprises: a sixth low-voltage transistor and a seventh low-voltage transistor;
wherein a second terminal of the sixth low-voltage transistor is electrically connected to the power port of the printed circuit board, a first terminal of the sixth low-voltage transistor is electrically connected to a second terminal of the seventh low-voltage transistor, a control terminal of the sixth low-voltage transistor is electrically connected between the first terminal of the sixth low-voltage transistor and the second terminal of the seventh low-voltage transistor, and a first terminal of the seventh low-voltage transistor and the a control terminal of the seventh low-voltage transistor are both electrically connected between the control terminal of the seventh high-voltage transistor and the control terminal of the eighth high-voltage transistor.

11. A vehicle-mounted circuit, comprising: a controller, a low dropout linear regulator, a first reverse connection protection diode, a second reverse connection protection diode, and an automotive-grade chip; wherein the automotive-grade chip comprises a plurality of reverse connection protection circuits, a plurality of ports corresponding to the plurality of reverse connection protection circuits respectively, and an internal circuit assembly; wherein,
a reverse connection protection circuit of the plurality of reverse connection protection circuits is electrically connected between a port corresponding to the reverse connection protection circuit and the internal circuit assembly, and the port is further electrically connected to the controller or electrically connected between the controller and the low dropout linear regulator;
the reverse connection protection circuit is configured to, in a case that a voltage at the port corresponding to the reverse connection protection circuit is equal to a reverse connection voltage of the controller, cut off a pathway between the port and the internal circuit assembly and/or control the internal circuit assembly to stop functioning;
an anode of the second reverse connection protection diode is electrically connected to the power port of the printed circuit board, a cathode of the second reverse connection protection diode is electrically connected to an input terminal of the low dropout linear regulator, an output terminal of the low dropout linear regulator is electrically connected to an input terminal of the controller, and a ground terminal of the controller is electrically connected to a ground port of a printed circuit board; and
a first port and a serial data output port of the automotive-grade chip are electrically connected to the controller, a serial peripheral interface of the automotive-grade chip is electrically connected between an output terminal of the low dropout linear regulator and a voltage input terminal of the controller, a power port of the automotive-grade chip is electrically connected to a power port of the printed circuit board, a ground port of the automotive-grade chip is electrically connected to an anode of the first reverse connection protection diode, and a cathode of the first reverse connection protection diode is electrically connected to the ground port of the printed circuit board.

12. The vehicle-mounted circuit according to claim 11, wherein the plurality of reverse connection protection circuits comprise: a first reverse connection protection circuit, a second reverse connection protection circuit, and a third reverse connection protection circuit; wherein
a port corresponding to the first reverse connection protection circuit is a serial peripheral interface, a port corresponding to the second reverse connection protection circuit is a first port, and a port corresponding to the third reverse connection protection circuit is a serial data output port; and
the internal circuit assembly comprises a first internal circuit and a second internal circuit; wherein
the first reverse connection protection circuit is electrically connected to the first internal circuit, the second internal circuit, and the third reverse connection protection circuit, the second reverse connection protection circuit is electrically connected between the first port and the first internal circuit, the third reverse connection protection circuit is electrically connected between the serial data output port and the second internal circuit, and the third reverse connection protection circuit is further electrically connected to the serial peripheral interface;
the first reverse connection protection circuit is configured to, in a case that a voltage at the serial peripheral interface is equal to the reverse connection voltage, cut off a pathway between the serial peripheral interface and the first internal circuit, cut off a pathway between the serial peripheral interface and the second internal circuit, and cut off a pathway between the serial peripheral interface and the third reverse connection protection circuit;
the second reverse connection protection circuit is configured to, in response to a voltage at the first port being equal to the reverse connection voltage, cut off a pathway between the first port and the first internal circuit; and
the third reverse connection protection circuit is configured to, in response to a voltage at the serial data output port being equal to the reverse connection voltage, control the second internal circuit to stop functioning.

13. The vehicle-mounted circuit according to claim 12, wherein the first reverse connection protection circuit comprises: a first high-voltage transistor, a first low-voltage transistor, a second low-voltage transistor, and a first clamp diode, and a first current source; wherein
a first terminal of the first high-voltage transistor is electrically connected to the serial peripheral interface, a second terminal of the first high-voltage transistor is electrically connected to the first internal circuit, the second internal circuit, and the third reverse connection protection circuit, a first terminal of the first current source is connected to a charge pump output voltage of the automotive-grade chip, a second terminal of the first current source is electrically connected to a cathode of the first clamp diode, an anode of the first clamp diode is electrically connected to a second terminal of the second low-voltage transistor, a first terminal of the second low-voltage transistor is electrically connected to a second terminal of the first low-voltage transistor, a first terminal of the first low-voltage transistor is electrically connected to a ground port of the automotive-grade chip, a control terminal of the first high-voltage transistor is electrically connected between the second terminal of the first current source and the cathode of the first clamp diode, a control terminal of the second low-voltage transistor is electrically connected between the first terminal of the second low-voltage transistor and the second terminal of the first low-voltage transistor, and a control terminal of the first low-voltage transistor is electrically connected between the first terminal of the first low-voltage transistor and the ground port of the automotive-grade chip.

14. The vehicle-mounted circuit according to claim 12, wherein the second reverse connection protection circuit comprises: a first resistor and a second high-voltage transistor;
wherein a first terminal of the first resistor is electrically connected to the first port, a second terminal of the first resistor is electrically connected to a first terminal of the second high-voltage transistor, a second terminal of the second high-voltage transistor is electrically connected to a second input terminal of the first internal circuit, and a control terminal of the second high-voltage transistor is connected to a reference voltage.

15. The vehicle-mounted circuit according to claim 12, wherein the first port comprises at least one of a serial clock port and a serial data input port.

16. The vehicle-mounted circuit according to claim 12, wherein the third reverse connection protection circuit comprises: a second clamp diode, a third clamp diode, a fourth clamp diode, a second resistor, a third resistor, a fourth resistor, a fifth resistor, a third high-voltage transistor, a third low-voltage transistor, a fourth low-voltage transistor, and a fifth low-voltage transistor; wherein
the serial peripheral interface is electrically connected to the second internal circuit, a cathode of the third clamp diode is electrically connected between the serial peripheral interface and the second internal circuit, an anode of the third clamp diode is electrically connected to a first terminal of the second resistor, a second terminal of the second resistor is electrically connected to a first terminal of the third resistor, and a second terminal of the third resistor is electrically connected to a ground port of the automotive-grade chip;
a cathode of the second clamp diode is electrically connected between the serial peripheral interface and the second internal circuit, an anode of the second clamp diode is electrically connected to a second terminal of the third high-voltage transistor, a first terminal of the third high-voltage transistor is electrically connected to the ground port of the automotive-grade chip, a control terminal of the third high-voltage transistor is electrically connected between the anode of the third clamp diode and the first terminal of the second resistor, and the second internal circuit is further electrically connected between the anode of the second clamp diode and the second terminal of the third high-voltage transistor; and
a cathode of the fourth clamp diode, a control terminal of the third low-voltage transistor, and a control terminal of the fourth low-voltage transistor are all electrically connected between the second terminal of the second resistor and the first terminal of the third resistor, an anode of the fourth clamp diode, a second terminal of the third low-voltage transistor, a second terminal of the fourth low-voltage transistor, and a second terminal of the fifth low-voltage transistor are all electrically connected between the second terminal of the third resistor and the ground port of the automotive-grade chip, a first terminal of the third low-voltage transistor is electrically connected to the second internal circuit, a first terminal of the fourth low-voltage transistor is electrically connected to the first reverse connection protection circuit via the fourth resistor, a control terminal of the fifth low-voltage transistor is electrically connected between the first terminal of the fourth low-voltage transistor and the fourth resistor, and a first terminal of the fifth low-voltage transistor is electrically connected between the second internal circuit and the second terminal of the third high-voltage transistor via the fifth resistor.
